(19) United States
(12) Patent Application Publication
(10) Pub. No.: US 2026/0036654 A1
(43) Pub. Date: Feb. 5, 2026

(54) MAGNETIC SENSOR, MAGNETIC SENSOR CONTROLLING METHOD, AND MAGNETIC SENSOR CONTROLLING PROGRAM

(71) Applicant: TDK Corporation, Tokyo (JP)

(72) Inventor: Yosuke KOMASAKI, Tokyo (JP)

(73) Assignee: TDK Corporation, Tokyo (JP)

(21) Appl. No.: 19/280,758

(22) Filed: Jul. 25, 2025

(30) Foreign Application Priority Data
Aug. 1, 2024 (JP) 2024-125998

(51) Int. Cl. G01R 33/09; G01R 33/00

(52) U.S. Cl. CPC G01R 33/098; G01R 33/0023; G01R 33/091; G01R 33/093

(57) ABSTRACT

A magnetic sensor includes: a magnetoresistive element connected between a power source and the ground, having a fixed layer the magnetization of which is fixed, a free layer having a free magnetization that forms a vortex configuration when there is no external magnetic field, and a non-magnetic layer provided between the fixed layer and the free layer; and a current changing circuit for changing a current value of a current flowing through the magnetoresistive element.

### CROSS-REFERENCE TO RELATED APPLICATIONS

This application claims the benefit of Japanese Priority Patent Application No. 2024-125998 filed on Aug. 1, 2024, the entire contents of which are incorporated herein by reference.

### FIELD

The present disclosure relates to a magnetic sensor, a magnetic sensor controlling method, and a magnetic sensor controlling program.

### BACKGROUND

Magnetic sensors using magnetoresistive elements including a vortex free layer have been attracting attention. Vortex free layers are characterized by their low magnetic hysteresis, because the vortex free layer forms a vortex with stable magnetization without an external magnetic field (see Japanese Translation of PCT Application No. 2022-529884, for example).

### SUMMARY

In the free layer of a magnetoresistive element having a vortex free layer, the core position, which is the center of the vortex of magnetization, becomes displaced in response to an external magnetic field. However, if the magnetic material forming the free layer has any defect such as a grain boundary or a crystal defect obstructing the displacement of the magnetization, on the path of the positional change of the core, the core temporarily gets caught at the position, and smooth displacement of the core in response to an external magnetic field is obstructed.

As a result, reproducibility of the hysteresis loop may deteriorate, and the usefulness of the magnetoresistive element having a vortex free layer may be impaired. To address this issue, in the magnetoresistive element disclosed in Japanese Translation of PCT Application No. 2022-529884, an indentation is provided to an edge of the free layer, so that the core is formed by the indentation highly reproducibly. Therefore, even if there is any defect in the ferromagnetic layer forming the free layer, the core is allowed to displace and to reciprocate along the same path. Although this method can improve the reproducibility of the magnetic sensor, as long as the core gets caught by a defect, the displacement of the core in accordance with a change in the external magnetic field is obstructed, and the linearity of the magnetic sensor deteriorates.

A magnetic sensor according to a first aspect of the present disclosure includes a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer; and a current changing circuit that changes a current value of a current flowing through the magnetoresistive element.

A magnetic sensor controlling method according to a second aspect of the present disclosure includes the steps of: causing a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer, to detect an external magnetic field without causing a current changing circuit capable of changing a current value of a current flowing through the magnetoresistive element to change the current value; and causing the current changing circuit to change the current value during a non-detection period in which the external magnetic field is not detected.

A magnetic sensor controlling program according to a third aspect of the present disclosure causes a computer to execute the steps of: causing a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer, to detect an external magnetic field without causing a current changing circuit capable of changing a current value of current flowing through the magnetoresistive element, to change the current value; and causing the current changing circuit to change the current value during a non-detection period in which the external magnetic field is not detected.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a conceptual schematic illustrating the overall configuration of a magnetic sensor according to one example embodiment of the present disclosure;

FIGS. 2A to 2C are schematics illustrating displacements of a vortex configuration of free magnetization in a virtual magnetoresistive element, with respect to a change in an external magnetic field;

FIG. 3 is a graph illustrating a magnetization curve of the free layer of the virtual magnetoresistive element;

FIG. 4 is a schematic illustrating an example of displacements of the core in a realistic magnetoresistive element, with respect to a change in the external magnetic field;

FIG. 5 is a graph illustrating an example of a magnetization curve in the linear region of the realistic magnetoresistive element;

FIG. 6 is a graph illustrating an example of a magnetization curve of a free layer in a linear region of the magnetoresistive element according to the one example embodiment of the present disclosure;

FIG. 7 is a graph illustrating a temporal change in the value of the current flowing through the magnetoresistive element;

FIG. 8 is a flowchart of control processing executed by a control module;

FIG. 9 is a conceptual schematic illustrating the overall configuration of a magnetic sensor according to a modification of the present disclosure; and

FIG. 10 is a graph illustrating a temporal change in the value of the current flowing through the magnetoresistive element according to the modification.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

An embodiment of the present disclosure will now be described with reference to the accompanying drawings. Note that elements designated by same reference signs in the respective drawings share an identical or a similar configuration. In addition, when structures sharing an identical or a similar configuration exist in plurality in each drawing, some structures may be accompanied with signs while others may not in order to avoid complication. Note that the disclosure related to the scope of aspects is not limited to the example embodiment described below. In addition, not all of the components described in the example embodiment are essential as means for solving the problem.

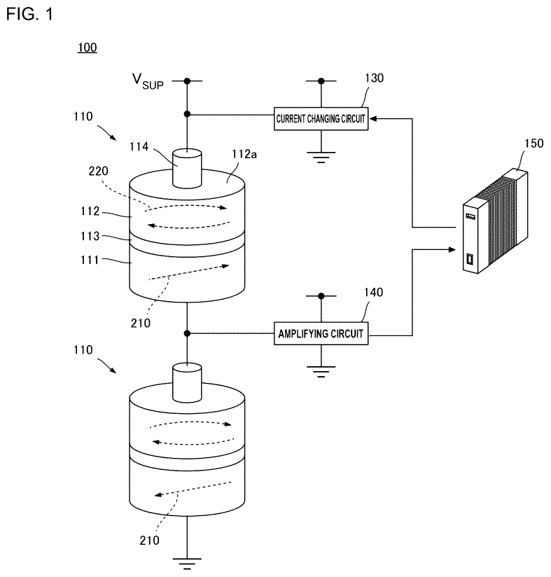

FIG. 1 is a schematic illustrating the overall configuration of a magnetic sensor 100 according to the one example embodiment. The magnetic sensor 100 may include two magnetoresistive elements 110, a current changing circuit 130, an amplifying circuit 140, and a control module 150. The two magnetoresistive elements 110 are connected to each other in series between a constant voltage source and the ground to form a half-bridge circuit. The constant voltage source supplies a constant supply voltage V_{SUP} to the half bridge circuit. The two magnetoresistive elements 110 are disposed in such a manner that the magnetizations of their respective fixed layers are directed oppositely to each other, so as to have opposing axes of magnetic detection. The respective resistance values change accordingly to the external magnetic field, in a manner complementing each other, in a linear region. As a result, the output voltage at a connection point between the two magnetoresistive elements 110 changes correspondingly to the intensity of the external magnetic field. The supply voltage V_{SUP} does not need to be a constant voltage as long as the voltage is known, and may be an AC voltage supplied from an AC power source, for example. At this time, the output voltage at the connection point between the two magnetoresistive elements 110 changes correspondingly to the intensity of the external magnetic field and to the known supply voltage V_{SUP}.

In the description hereunder, it is assumed that the magnetoresistive elements 110 used in the magnetic sensor 100 are tunneling magnetoresistive (TMR) elements, but may be any current-perpendicular-to-plane (CPP) spin valve magnetoresistive elements (MR elements), and may be giant magnetoresistive (GMR) elements, for example. In a CPP magnetoresistive element, a current magnetic field generated by applying a current to the magnetoresistive element follows the rotational direction of the vortex, or reversal of the rotational direction of the vortex. Although, in this embodiment, the two magnetoresistive elements 110 forming the half-bridge circuit have the same structure, the two magnetoresistive elements 110 may be provided by combining the magnetoresistive elements with different structures or of different types.

Each of the magnetoresistive elements 110 may include a fixed layer 111, a free layer 112, a non-magnetic layer 113, and a lead electrode 114. The fixed layer 111 is what is called a pinned layer having a fixed magnetization 210, in which the magnetization is fixed to one direction. The two magnetoresistive elements 110 are adjusted in such a manner that their respective fixed magnetizations 210 are directed to opposite directions, with the two magnetoresistive elements 110 fixed to the substrate, so that the respective resistances change oppositely to each other in the presence of the external magnetic field. The fixed layer 111 may be cylindrical or elliptic cylindrical in shape, for example, as a whole.

The free layer 112 is what is called a free layer having a free magnetization 220 that forms a vortex configuration while there is no external magnetic field. The free layer 112 may also be cylindrical or elliptic cylindrical in shape, as a whole, in the same manner as the fixed layer 111. The non-magnetic layer 113 is interposed between the fixed layer 111 and the free layer 112. In this embodiment in which the magnetoresistive element 110 is a TMR element, the non-magnetic layer 113 is a tunnel barrier layer. The fixed layer 111, the non-magnetic layer 113, and the free layer 112 are laminated in the order listed herein, and may have a cylindrical or elliptic cylindrical shape, as a whole. The shapes of the fixed layer 111, the non-magnetic layer 113, and the free layer 112 do not necessarily need to be the same.

The fixed layer 111 and the free layer 112 may be made of a ferromagnetic film containing a material such as NiFe, NiFeCo, Fe, FeCo, Co, or CoFeB. The non-magnetic layer 113 is a thin insulating layer, and is adjusted to a thickness at which electron tunneling occurs between the fixed layer 111 and the free layer 112. In the magnetoresistive element 110 thus prepared, the resistance between the fixed layer 111 and the free layer 112 remains low when there is relatively greater free magnetization 220 in the same direction as the direction of the magnetization of the fixed magnetization 210; and the resistance between the fixed layer 111 and the free layer 112 increases when there is relatively greater free magnetization 220 in the direction opposite to the direction of the magnetization of the fixed magnetization 210.

The lead electrode 114 may be a columnar electrode having a contact surface that is directly connected to an end surface 112a of the free layer 112, on the opposite side of a contact surface in contact with the non-magnetic layer 113, and that has an area smaller than the area of the end surface 112a. By setting the area of the contact surface of the lead electrode 114 smaller than the area of the end surface 112a, the free layer 112 is less affected by effects (such as stress) caused by bonding the lead electrode 114 to the end surface 112a, for example. In addition, by making the contact surface small, the path of a current flow becomes limited, so that the current magnetic field may be effectively applied to the free layer, compared with an example in which the contact surface is larger. By using the lead electrode 114 having such a shape, a magnetic sensor having higher linearity may be achieved, with less variation in the displacements of the vortex configuration of the free magnetization 220 in the free layer 112.

Because the two magnetoresistive elements 110 are connected in series between the constant voltage source for supplying the constant supply voltage V_{SUP} and the ground, the current value of the current flowing through each of the magnetoresistive elements 110 is determined by the sum of resistances of the respective magnetoresistive elements 110, the sum changing in accordance with the magnitude of the external magnetic field. In this embodiment, apart from the current value thus determined, the current changing circuit 130 for forcibly changing the current value of the current flowing through each of the magnetoresistive elements 110 is provided. As the current changing circuit 130, it is possible to use a one-shot circuit that instantaneously increases or decreases a current value, or a multi-vibrator circuit capable of changing the current value in the form of a pulse wave or a sine wave, for example. The current changing circuit 130 may be integrated with the constant voltage source. In such a case, the current changing circuit 130 may be implemented as a part of a circuit element implementing the constant voltage source, for example.

The current changing circuit 130 may be configured to change the current value of the current flowing through the magnetoresistive elements 110 in response to a control command received from the control module 150. The current changing circuit 130 may be provided so as to change the current values of the two magnetoresistive elements 110 simultaneously, as illustrated, or may be provided individually for each of the two magnetoresistive elements 110. Significance of and timing for changing the current value of the magnetoresistive elements 110 will be described later in detail.

The amplifying circuit 140 is a circuit for amplifying and transmitting the voltage value at the connection point between the two magnetoresistive elements 110 to the control module 150, and may include an operational amplifier, for example. The control module 150 functions as a control unit for controlling the magnetic sensor 100, and may include a processor (central processing unit (CPU)) for executing a program and a memory for storing the program, various parameters, and the like. The control module 150 may be configured to cooperate with a processor chip such as an application-specific integrated circuit (ASIC) or a graphic processing unit (GPU). Note that the control module 150 may be implemented as a system on a chip (SoC) having processing for controlling the magnetic sensor 100 incorporated therein.

The control module 150 reads a controlling program stored in the memory, and executes various types of processing pertinent to the magnetic sensor 100. In particular, the control module 150 performs processing such as giving a control command to the current changing circuit 130, as mentioned above, and calculating the intensity of the external magnetic field using an output signal received from the amplifying circuit 140. The control module 150 may be connected to another computer or the like over a network, for example, and may control the magnetic sensor 100 in response to a command issued by the other computer. The magnetic sensor 100 may be encapsulated into one package, for example, and may include a detecting unit that includes the two magnetoresistive elements 110, and a processing unit that includes the current changing circuit 130, the amplifying circuit 140, and the control module 150.

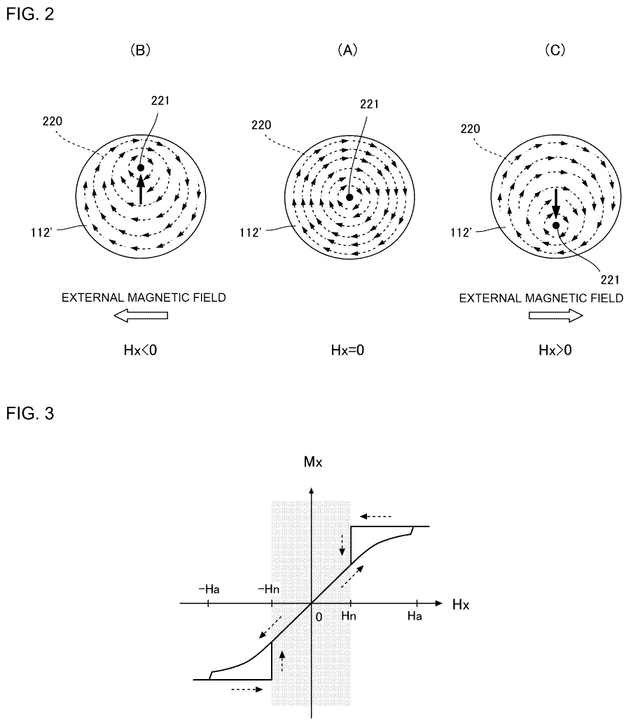

FIGS. 2A to 2C are schematics illustrating displacements of a vortex configuration of the free magnetization 220 with respect to changes in the external magnetic field Hx, in a virtual magnetoresistive element without any defects in a free layer 112′. FIG. 2A is a schematic illustrating a vortex configuration when Hx=0, that is, when there is no external magnetic field. While there is no external magnetic field, the core 221 illustrated as a black dot is near the center of a cross section of the free layer 112′, and the free magnetization 220 indicated by the dotted arrows forms a substantially concentric vortex around the core 221.

FIG. 2B is a schematic illustrating a vortex configuration when an external magnetic field is applied in one direction that is orthogonal to the central axis of the free layer 112′ (the direction of the white arrow). When such an external magnetic field is applied to the configuration in FIG. 2A in the direction of the white arrow (where Hx<0), the core 221 becomes displaced in a cross-sectional direction of the free layer 112′, and orthogonally to the external magnetic field, as indicated by the thick black arrow. With the core 221 having gone through such displacements, the vortex configuration of the free magnetization 220 is no longer concentric with respect to the core 221 as the center. Instead, it shifts to a vortex configuration in which the side of the free layer 112′ with a shorter distance between the outer perimeter of the free layer 112′ and the displaced core 221 has relatively smaller free magnetization 220, whereas the side with a longer distance between the outer perimeter and the displaced core 221 has relatively larger free magnetization 220. Therefore, in the illustrated example, the free magnetizations 220 having a component in the direction of the external magnetic field become greater than the free magnetizations 220 having a component in the opposite direction to the external magnetic field. At this time, when the direction of the fixed magnetization 210 and the direction of the external magnetic field are the same, the resistance value of the magnetoresistive element decreases. Conversely, when the direction of the fixed magnetization 210 is opposite to the direction of the external magnetic field, the resistance value of the magnetoresistive element increases.

FIG. 2C is a schematic illustrating a vortex configuration when an external magnetic field is applied in one direction that is orthogonal to the central axis of the free layer 112′ but in the direction opposite to that in FIG. 2B (the direction of the white arrow). When such an external magnetic field is applied to the configuration in FIG. 2A in the direction of the white arrow (Hx>0), the core 221 become displaced in a cross-sectional direction of the free layer 112′, and orthogonally to the external magnetic field, as indicated by the thick black arrow. With the core 221 having gone through such displacements, the vortex configuration of the free magnetization 220 is no longer concentric with respect to the core 221 as the center. Instead, it shifts to a vortex configuration in which the side nearer to the perimeter of the free layer 112′ has relatively smaller free magnetization 220, whereas the side further away from the perimeter has relatively larger free magnetization 220. Therefore, in the illustrated example, the free magnetizations 220 having a component in the direction of the external magnetic field become greater than the free magnetizations 220 having a component in the opposite direction to the external magnetic field. At this time, when the direction of the fixed magnetization 210 is opposite to the direction of the external magnetic field, the resistance value of the magnetoresistive element increases. Conversely, when the direction of the fixed magnetization 210 and the direction of the external magnetic field are the same, the resistance value of the magnetoresistive element decreases.

FIG. 3 is a graph illustrating a magnetization curve of the free layer of the virtual magnetoresistive element described with reference to FIGS. 2A to 2C. The horizontal axis represents the external magnetic field Hx, and the vertical axis represents normalized magnetization Mx of a component in the direction of the detection axis of the free magnetization 220.

As indicated, the magnetization curve increases in accordance with an increase in the external magnetic field, until the external magnetic field reaches Ha. Once the external magnetic field reaches Ha, the vortex configuration vanishes and the magnetization saturates on the positive side. As the external magnetic field gradually decreases from that level, the magnetization remains at the saturation level for a while. Once the external magnetic field decreases to a nucleation field Hn, which refers to the magnetic field of vortex nucleation point with a core, a core is formed again, a vortex configuration is restored, and the magnetization drops instantaneously approximately to the same level as that taken when the external magnetic field has increased. As the external magnetic field decreases further, the magnetization decreases by following approximately the same path followed at the time when the external magnetic field has increased, but in the opposite direction.

As the external magnetic field decreases further, the magnetization decreases in accordance with a decrease in the external magnetic field, until the external magnetic field reaches-Ha. Once the external magnetic field reaches-Ha, the vortex configuration vanishes and the magnetization saturates on the negative side. As the external magnetic field increases gradually from that level, the magnetization remains at the saturation level for a while. Once the external magnetic field increases to a core-generating magnetic field-Hn, the core is formed again, a vortex configuration is restored, and the magnetization surges instantaneously approximately to the same level taken when the external magnetic field has decreased. Thereafter, the magnetization increases by following approximately the same path followed at the time when the external magnetic field has decreased, but in the opposite direction.

As indicated as shaded in the graph, between-Hn and Hn in which the free magnetization 220 forms a vortex, the magnetization curve exhibits a small hysteresis and excellent linearity in the magnetization component values with respect to an increase and a decrease of an external magnetic field. Therefore, by using this linear region as a region for detecting the external magnetic field, it is possible to achieve a magnetic sensor capable of achieving both high reproducibility of the hysteresis loop and linearity with respect to a change in the external magnetic field.

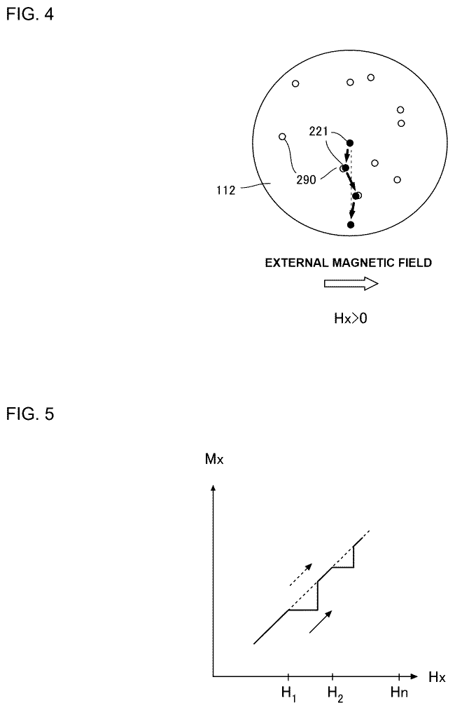

However, the material of the actual free layers 112 may have random defects, and such defects may prevent the core 221 from becoming displaced in accordance with a change in the external magnetic field. FIG. 4 is a schematic illustrating an example of displacements of the core 221 with respect to a change in the external magnetic field in a realistic magnetoresistive element 110. Specifically, the thick arrows schematically illustrate how the core 221 is displaced in response to a gradual increase of the external magnetic field from zero (Hx>0).

White circles indicate representative defects 290 in the material of the free layer 112. Without any defect 290, the core 221 would become displaced substantially linearly, as indicated by the dotted arrow. However, because there are some defects 290 along the path in reality, the core 221 may get caught by the defects 290. Once the core 221 gets caught by a defect, even with some increase or decrease of the external magnetic field, the core 221 does not become displaced in accordance therewith. In other words, during that time, the vortex configuration of the free magnetization 220 does not change. When the external magnetic field thereafter increases or decreases beyond a certain degree, the core 221 goes out of the defect 290 and starts becoming displaced again.

FIG. 5 is a graph illustrating an example of a magnetization curve in the linear region of a realistic magnetoresistive element 110, without the operation of the current changing circuit 130 according to this embodiment. Specifically, the thick line indicates the magnetization curve in the case where the core 221 gets caught by different defects 290 at the times at which the external magnetic field is at H₁ and H₂, respectively, and the dotted line indicates the magnetization curve when there is no defect 290.

Once the core 221 gets caught by the defect 290, even if the external magnetic field increases, the position of the core of the free magnetization 220 does not change for a while, as described above, so that the magnetization Mx during the period remains substantially constant. As the external magnetic field increases beyond a certain degree, the core 221 goes out of the defect 290 and begins to become displaced again; however, this behavior will be observed as hysteresis until the core 221 goes out of the defect 290. This hysteresis causes a deterioration in the reproducibility in the outputs of the magnetic sensor. While the core is getting caught by the defect 290, although the external magnetic field increases, the magnetization Mx does not change or the changes is smaller than it should, so that the resistance value of the magnetoresistive element 110 does not change as it should. In such a case, there may be some error in the measurement result of the external magnetic field. Therefore, the magnetic sensor 100 according to this embodiment uses the current changing circuit 130 to reduce the hysteresis caused by the defect 290 and to improve the reproducibility of the hysteresis loop.

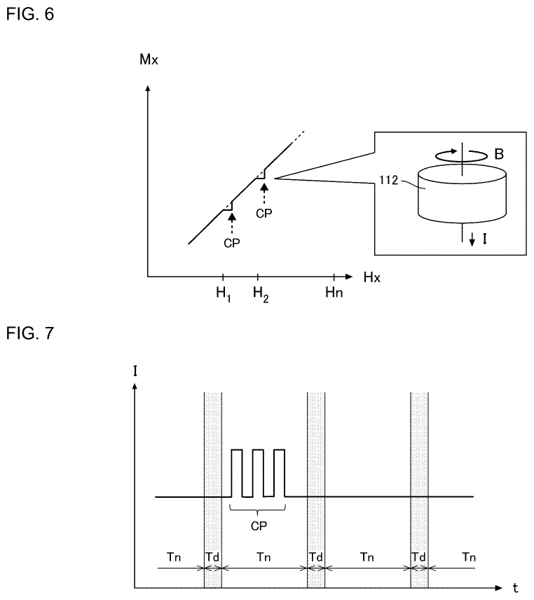

FIG. 6 is a graph illustrating an example of a magnetization curve in the linear region of the magnetoresistive element 110 with the operation of the current changing circuit 130 according to this embodiment. In this embodiment, the current value of the current flowing through the magnetoresistive element 110 is changed forcibly by cyclically causing the current changing circuit 130 to operate, for example, as will be described later. The current changing circuit 130 forcibly increases or decreases the value of the current flowing through the magnetoresistive element 110 by applying a voltage that is different from the supply voltage V_{SUP} to the magnetoresistive element 110.

As the value of the current flowing through the magnetoresistive element 110 is increased or decreased, the shape of the vortex of the free layer magnetization is changed by a current magnetic field attributable to the increase or the decrease of the current (for example, a magnetic field B indicated by the arrow in the solid line in the drawing), and the core 221 quickly goes out of the defect 290, and goes back to the original magnetization curve. The example in the graph indicates how the core 221 gets caught by the defect 290 at the timings at which the external magnetic field is H₁ and H₂, respectively, and the current changing circuit 130 supplies a current pulse CP at the timings subsequent thereto. After the current pulse CP is supplied, the core 221 goes back to the magnetization curve that is the curve when there is no defect 290. By supplying a current pulse before measuring the external magnetic field, for example, it is possible to reduce the hysteresis in the output voltage and to improve reproducibility of the hysteresis loop.

FIG. 7 is a graph illustrating a temporal change in the value of the current flowing through the magnetoresistive element 110 when the external magnetic field is constant. The horizontal axis represents the time elapsed, and the vertical axis represents the current value.

Because the magnetic sensor 100 according to this embodiment is a sensor for detecting the external magnetic field, the control module 150 is configured to cause the amplifying circuit 140 to amplify the voltage at the connection point between the two magnetoresistive elements 110, cyclically or at some timing, and to detect the magnitude of the external magnetic field, for example. During detection periods Td (the shaded parts of the graph) for detecting the magnitude of the external magnetic field, the control module 150 does not cause the current changing circuit 130 to operate, in order to detect a divided voltage from the two magnetoresistive elements 110 resultant of supplying the supply voltage V_{SUP}.

The control module 150 causes the current changing circuit 130 to operate in non-detection periods Tn other than the detection periods Td. The graph indicates how the current changing circuit 130 is caused to operate and to apply the current pulse CP to the magnetoresistive element 110 in one non-detection period Tn.

In order to cause the current changing circuit 130 to operate cyclically, the control module 150 may control to assign the period for operating the current changing circuit 130 at least to the non-detection period Tn, so that such a period of the operation does not overlap with the detection period Td. To prioritize the detection of the external magnetic field when the detection period Td overlaps with the period for operating the current changing circuit 130, an adjustment may be made so that the operation of the current changing circuit 130 is skipped.

Furthermore, because the magnetic sensor 100 according to this embodiment assumes that the external magnetic field is detected within the range of the linear region described with reference to FIG. 3, the control module 150 causes the current changing circuit 130 to operate between-Hn and Hn where the free magnetization 220 forms a vortex. Accordingly, the control module 150 may cause the current changing circuit 130 to start changing the current value upon detecting the timing Hn at which the core is formed again after the external magnetic field has gradually decreased from the magnitude greater than Hn, or the timing of −Hn at which the core is formed again after the external magnetic field has gradually increased from the magnitude less than −Hn. At the timing of the magnetic field Hn or −Hn at which the core is formed, the direction of the rotation of the vortex formed in the free magnetization 220, that is, whether the rotation of the vortex thus formed is in the clockwise or counter-clockwise direction, is determined randomly, as long as no particular external effect is given. In this regard, by controlling the direction of the current applied by the current changing circuit 130 at this timing, the magnetic sensor 100 may direct the rotation of the vortex formed in the free magnetization 220 to intended one of these directions. In other words, because the current magnetic field formed by the current applied by the current changing circuit 130 is generated in the clockwise or counter-clockwise direction in the free layer 112, as mentioned earlier, by controlling the direction of the current applied at the timing the vortex is formed, it is possible to direct and settle the direction of rotation of the vortex formed in the free magnetization 220 to the intended direction. By increasing the reproducibility of the rotating direction of the vortex, the reproducibility of the hysteresis loop may be further improved.

Furthermore, the degree by which the current changing circuit 130 increases or decreases the current value of the magnetoresistive element 110 may be any degree by which the position of the core 221 may be displaced, and is determined on the basis of the characteristics of the free layer 112 to be used, or the direction and the magnitude of the external magnetic field at that time. For example, when the magnitude of the external magnetic field is great, the control module 150 may limit the increase in the current value to an extent not causing the core 221 to vanish. It may be also possible to control the current value to increase instantaneously during the process in which the external magnetic field is gradually increasing, and to decrease instantaneously during the process in which the external magnetic field is gradually decreasing. When the control module 150 attempts to change the position of the core 221, the control module 150 increases or decreases the current value of the magnetoresistive element 110 at least once; however, the control module 150 may also repeat increasing and decreasing the current value continuously to reduce variations in the width by which the current is changed per one time. In such a case, a pulse wave or a sine wave may be used to increase and decrease the current value. In order to change the position of the core 221 effectively, the control module 150 may be configured to control the current changing circuit 130 to apply a one-shot pulse wave by which a current of an appropriate magnitude is applied.

When a magnetoresistive element 110 the resistance value of which changes not only in response to the external magnetic field but also in response to temperature, the control module 150 may measure the temperature of the magnetoresistive element 110 and adjust the current value for displacement, in accordance with the temperature. In such a case, a temperature detection sensor is disposed near the magnetoresistive element 110, and the control module 150 causes the current changing circuit 130 to operate in accordance with the detection result of the temperature detection sensor. The control module 150 may also be configured to estimate the temperature from the resistance value of the magnetoresistive element 110 on the basis of a preset relationship between the temperature and the resistance value of the magnetoresistive element 110, and adjust the current value on the basis of the estimated temperature, for example.

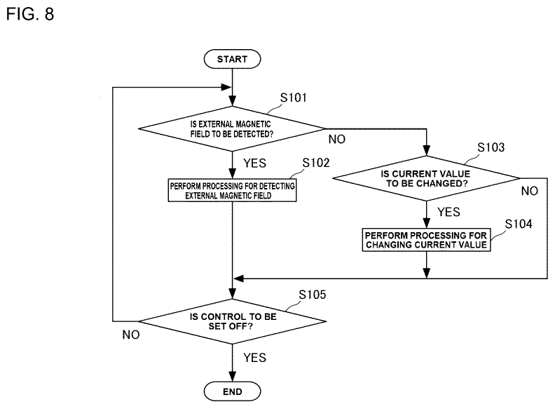

The sequence of processing performed by the control module 150 will now be summarized. FIG. 8 is a flowchart of the control processing executed by the control module. This sequence is initiated by a command for starting the process of detecting the external magnetic field.

At Step S101, the control module 150 checks whether the current timing is within the detection period for detecting the external magnetic field. If the current timing is within the detection period, the control is shifted to Step S102. If the current timing is outside the detection period, it is determined that the current timing is within the non-detection period, and the control is shifted to Step S103. Once the control is shifted to Step S102, the external magnetic field detection processing is executed at Step S102. Specifically, the voltage value output from the amplifying circuit 140 is acquired, is converted into a digital value, for example, and the digital value is transmitted to an external management device. The control is then shifted to Step S105.

Once the control is shifted from Step S101 to Step S103, the control module 150 checks whether it is the timing for changing the current value. If it is the timing for changing the current value, the control is shifted to Step S104 to cause the current changing circuit 130 to operate and to change the current value to be passed through the magnetic sensor 100. If the processing for changing the current value is finished at Step S104, or if it is determined that it is not the timing for changing the current value at Step S103, the control is shifted to Step S105.

Once the control is shifted to Step S105, the control module 150 checks whether a command for setting the control to OFF has been received from a user or an external device. If the command for setting the control OFF has not been received, the control goes back to Step S101, and the sequence of the processing is repeated. If the command for setting the control OFF has been received, the sequence of the processing is ended.

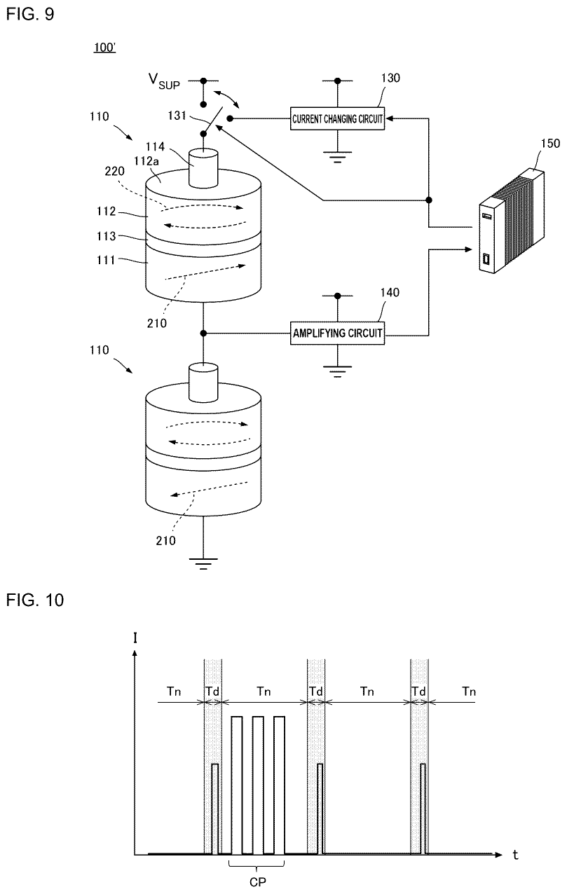

A modification of the disclosure described above will now be explained. FIG. 9 is a conceptual schematic illustrating the overall configuration of a magnetic sensor 100′ according to a modification of the present disclosure. The magnetic sensor 100′ is different from the magnetic sensor 100 in that the magnetic sensor 100 is provided with a switch 131, and the control module 150 is also configured to control the switch 131. The same components as those in the magnetic sensor 100 are assigned with the same reference numerals, and descriptions thereof will be omitted unless specified otherwise.

The switch 131 is a switch enabled to select which one or none of the supply voltage V_{SUP} and the current changing circuit 130 the magnetoresistive element 110 is to be connected, and is configured as a semiconductor switch, for example. A control module 150′ transmits a switching signal to the switch 131 at the timing for detecting the magnitude of the external magnetic field, to connect the magnetoresistive element 110 to the supply voltage V_{SUP}. A switching signal is also transmitted to the switch 131 at the timing for causing the current changing circuit 130 to operate, to connect the magnetoresistive element 110 to the current changing circuit 130. At the other timings, the state in which the magnetoresistive element 110 is connected to neither is maintained.

FIG. 10 is a graph illustrating a temporal change in the value of the current flowing through the magnetoresistive element 110 according to the modification. Because the control module 150 connects the magnetoresistive element 110 to the supply voltage V_{SUP} at the timing for detecting the magnitude of the external magnetic field, as described above, the switch 131 is isolated from both of the supply voltage V_{SUP} and the current changing circuit 130 at the timings other than the timings for detection, even during the detection period Td. Therefore, it is possible to suppress power consumption. In the same manner, because the control module 150 connects the magnetoresistive element 110 to the current changing circuit 130 at the timing for passing a current from the current changing circuit 130 to the magnetoresistive element 110, the switch 131 is kept isolated from both of the supply voltage V_{SUP} and the current changing circuit 130 even during the non-detection period Tn, at the timings other than those for passing the current. Therefore, it is possible to suppress power consumption.

It may be also possible for the control module 150 to control the current changing circuit 130 to operate only at the timing for passing the current to the magnetoresistive elements 110. That is, the current changing circuit 130 may be controlled to operate synchronously with the timing at which the switch 131 is connected to the current changing circuit 130. Furthermore, it may be also possible to, instead of causing the control module 150 to directly control the current changing circuit 130, configure the current changing circuit 130 to operate to apply a current to the magnetoresistive elements 110 when the switch 131 becomes connected to the current changing circuit 130, and to configure the control module 150 to control the switch 131, so that the current changing circuit 130 is caused to change the value of the current to be applied to the magnetoresistive elements 110. The switch 131 may be a toggle switch that connects the magnetoresistive element 110 to one of the supply voltage V_{SUP} and the current changing circuit 130. With such a configuration, by connecting the switch 131 to the current changing circuit 130 and controlling the current changing circuit 130 to the non-operating state, power consumption may be reduced.

Although the magnetic sensor 100 according to this embodiment has been described above, other various modifications of the aspects of the magnetic sensor 100 are still possible. For example, in the example described above, in order to detect an external magnetic field, the two magnetoresistive elements 110 are connected in series to form a half-bridge circuit, but the circuit configuration is not limited thereto. For example, it may be possible to form a full-bridge circuit by using four magnetoresistive elements 110. Furthermore, the magnetic sensor 100 may be configured by connecting one or more magnetoresistive elements 110 using a circuit configuration different from that of a bridge circuit. In a configuration of a circuit including a plurality of magnetoresistive elements 110, the magnetoresistive elements 110 may be wired in such a manner that the currents flowing through the magnetoresistive elements 110 are all in the same direction. That is, the magnetoresistive elements 110 may be configured to be affected uniformly by a change in the current magnetic field, the change being caused by changing the current with the current changing circuit 130.

The present disclosure may provide a magnetic sensor having higher reproducibility of a hysteresis loop with respect to a change in an external magnetic field, with improved linearity in the linear region.

1. A magnetic sensor comprising:
a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer; and
a current changing circuit that changes a current value of a current flowing through the magnetoresistive element.

2. The magnetic sensor according to claim 1, further comprising a control unit that causes the current changing circuit to change the current value in a non-detection period that is not a detection period for detecting an external magnetic field.

3. The magnetic sensor according to claim 2, wherein the control unit causes the current changing circuit to change the current value so as to change a position of a core of the vortex configuration.

4. The magnetic sensor according to claim 2, wherein the control unit causes the current changing circuit to change the current value at a timing during the non-detection period at least once.

5. The magnetic sensor according to claim 4, wherein the control unit causes the current changing circuit to repeat increasing and decreasing the current value continuously.

6. The magnetic sensor according to claim 3, wherein the control unit starts the non-detection period and causes the current changing circuit to change the current value upon detecting a timing at which the core is formed again in accordance with a change in an external magnetic field during the detection period.

7. The magnetic sensor according to claim 2, wherein the control unit causes the current changing circuit to change the current value based on a direction and magnitude of the external magnetic field detected during the detection period.

8. The magnetic sensor according to claim 2, wherein the control unit causes the current changing circuit to change the current value based on a temperature of the magnetoresistive element.

9. The magnetic sensor according to claim 1, wherein the magnetoresistive element further includes a columnar lead electrode that is directly connected to an end surface of the free layer and that has a contact surface, an area of which is smaller than an area of the end surface.

10. The magnetic sensor according to claim 1, wherein, when the magnetoresistive element is provided in plurality, the magnetoresistive elements are wired in a manner matching directions of currents in all of the magnetoresistive elements.

11. A magnetic sensor controlling method comprising the steps of:
causing a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer, to detect an external magnetic field without causing a current changing circuit capable of changing a current value of a current flowing through the magnetoresistive element to change the current value; and
causing the current changing circuit to change the current value during a non-detection period in which the external magnetic field is not detected.

12. The magnetic sensor controlling method according to claim 11, wherein, at the step of causing the current changing circuit, the current changing circuit is caused to change the current value so as to change a position of a core of the vortex configuration.

13. A magnetic sensor controlling program causing a computer to execute the steps of:
causing a magnetoresistive element that is connected between a power source and a ground, and that includes a fixed layer having a fixed magnetization, a free layer having a free magnetization that forms a vortex configuration without an external magnetic field, and a non-magnetic layer provided between the fixed layer and the free layer, to detect an external magnetic field without causing a current changing circuit capable of changing a current value of a current flowing through the magnetoresistive element to change the current value; and
causing the current changing circuit to change the current value during a non-detection period in which the external magnetic field is not detected.

14. The magnetic sensor controlling program according to claim 13, wherein, at the step of causing the current changing circuit to change the current value, the current changing circuit is caused to change the current value so as to change a position of a core of the vortex configuration.
